(19) United States
(12) Patent Application Publication
(10) Pub. No.: US 2026/0068677 A1
(43) Pub. Date: Mar. 5, 2026

(54) ELECTRONIC DEVICE WITH INTEGRATED SHEILD AND HEAT SPREADER

(71) Applicant: Texas Instruments Incorporated, Dallas, TX (US)

(72) Inventors: Jaimal Williamson, McKinney, TX (US); Jie Chen, Plano, TX (US); Rajen Manicon Murugan, Dallas, TX (US)

(21) Appl. No.: 18/821,952

(22) Filed: Aug. 30, 2024

(51) Int. Cl. H01L 23/552; H01L 21/3205; H01L 21/768; H01L 23/00; H01L 23/31; H01L 23/48; H01L 23/498

(52) U.S. Cl. CPC H01L 23/552

(57) ABSTRACT

An electronic device includes a substrate and a semiconductor die having conductive terminals along a first side, and a conductive shield with electrically and/or thermally conductive material that extends through the semiconductor die from the first side to an opposite second side, the conductive terminals coupled to respective conductive features of the substrate. A method includes forming via openings extending from a first side of a wafer to an opposite second side, forming a conductive shield that extends in the via openings and covers a portion of the second side of the wafer, and forming conductive terminals along the first side of the wafer.

### BACKGROUND

Flip chip, chip scale package (FCCSP) electronic devices offer advantages with respect to compact size and reliability. However, the FCCSP package configuration may suffer from limited ability to dissipate heat from the package due to the poor thermal conductivity of the mold compound. In addition, many circuits packaged in FCCSP form are susceptible to electromagnetic interference (EMI) or generate EMI and current device shielding techniques can add significant manufacturing cost.

### SUMMARY

In one aspect, an electronic device includes a substrate having conductive features, and a semiconductor die having opposite first and second sides, conductive terminals along the first side, and a conductive shield with conductive material that extends through the semiconductor die from the first side to the second side, the conductive terminals coupled to respective ones of the conductive features of the substrate.

In another aspect, a system includes a circuit board having a conductive feature, and an electronic device, including a substrate having conductive features, and a conductive terminal that is soldered to the conductive feature of the circuit board, and a semiconductor die having opposite first and second sides, conductive terminals along the first side, and a conductive shield with conductive material that extends through the semiconductor die from the first side to the second side, the conductive terminals coupled to respective ones of the conductive features of the substrate.

In a further aspect, a method includes forming via openings extending from a first side of a wafer to an opposite second side of the wafer, forming a conductive shield that extends in the via openings through the semiconductor die from the first side to the second side and covers a portion of the second side of the wafer, and forming conductive terminals along the first side of the wafer.

### BRIEF DESCRIPTION OF THE DRAWINGS

FIG. 1 is a partial sectional side elevation view of a flip chip ball grid array (FCBGA) chip scale package electronic device on a system circuit board taken along line 1-1 of FIG. 1A having a die with an integrated conductive metal shield attached to a substrate with conductors to extend the shield and provide thermal heat dissipation.

FIG. 1A is a top plan view of the electronic device of FIG. 1.

FIG. 2 is a flow diagram of a method of fabricating an electronic device.

FIGS. 3-14 are sectional side views of the electronic device of FIGS. 1 and 1A undergoing fabrication processing according to an implementation of the method of FIG. 2.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. In the following discussion and in the claims, the terms “including”, “includes”, “having”, “has”, “with”, or variants thereof are intended to be inclusive in a manner similar to the term “comprising”, and thus should be interpreted to mean “including, but not limited to”.

Unless otherwise stated, “about,” “approximately,” or “substantially” preceding a value means +/−10 percent of the stated value. One or more operational characteristics of various circuits, systems and/or components are hereinafter described in the context of functions which in some cases result from configuration and/or interconnection of various structures when circuitry is powered and operating. One or more structures, features, aspects, components, etc., may be referred to herein as first, second, third, etc., such as first and second terminals, first, second, and third, wells, etc., for ease of description in connection with a particular drawing, where such are not to be construed as limiting with respect to the claims. Various structures and methods of the present disclosure may be beneficially applied to an electronic apparatus such as an integrated circuit and manufacturing electronic devices. While such examples may be expected to provide various improvements, no particular result is a requirement of the present disclosure unless explicitly recited in a particular claim.

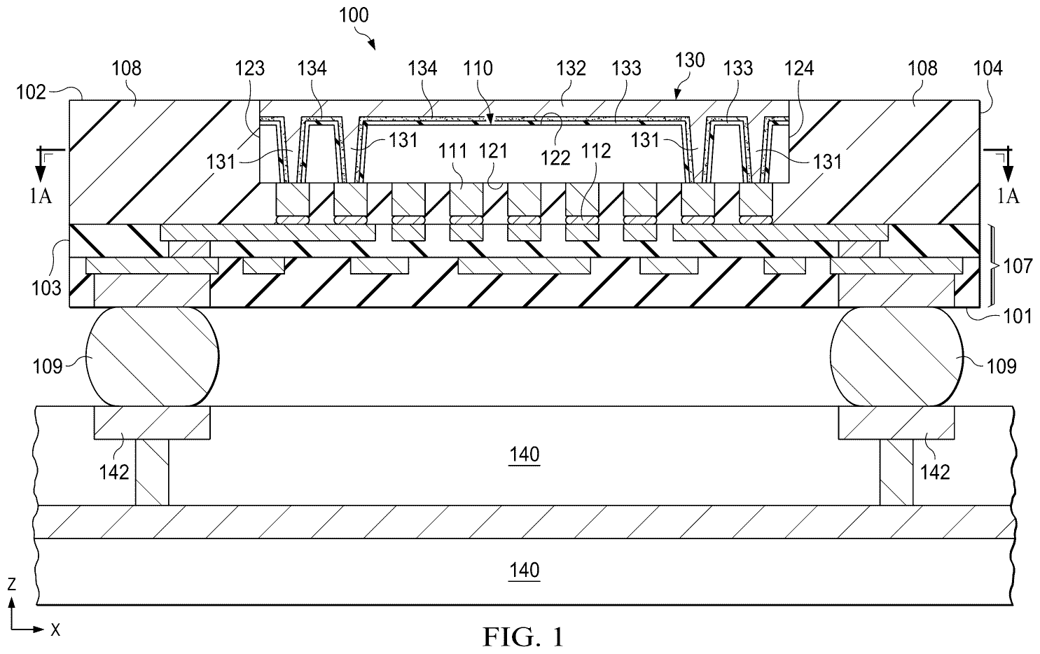

FIGS. 1 and 1A show an example flip chip ball grid array (FCBGA) electronic device 100 with an integrated conductive metal shield attached to a substrate with conductors to extend the shield and provide enhanced electromagnetic shielding and thermal heat dissipation. The electronic device 100 is illustrated in an example position in a three-dimensional space with respective first, second, and third mutually orthogonal directions X (FIGS. 1 and 1A), Y (FIG. 1A) and Z (FIG. 1). The electronic device 100 includes opposite first and second (e.g., bottom and top) sides 101 and 102 (FIG. 1) that are spaced apart from one another along the third direction Z. The electronic device 100 also includes third and fourth sides 103 and 104 that are spaced apart from one another along the first direction X, and fifth and sixth sides 105 and 106 (FIG. 1A) that are spaced apart from one another along the second direction Y.

The electronic device 100 includes a substrate 107 having conductive features. The substrate 107 extends along the first side 101 of the electronic device 100 and a package structure 108 (e.g., a molded plastic structure) extends from the top side of the substrate 107 to the second side 102 of the electronic device 100. In one example, the substrate 107 is a multilevel package substrate that can also be referred to a routable lead frame (RLF) or a FCCSP embedded trace substrate (ETS) or cored substrate with prepreg dielectric layers. The substrate 107 is a two level stacked structure with dielectric layers and patterned conductive metal features including trace layer features and conductive metal via features. In other examples, any suitable number of two or more levels can be used with trace and/or via layer features such as multilayer ETS or cored substrate for example 2 to 6 layers). The illustrated example is a ball grid array (BGA) package with solder ball terminals 109 connected to bottom side trace or via features of the substrate 107 to facilitate soldering to a host circuit board 140 as shown in FIG. 1. In another implementation, the substrate 107 can be soldered directly to a circuit board 140, with bottom side conductive features of the substrate 107 operating as conductive metal terminals for the electronic device 100. The substrate 107 and the solder ball terminals 109 provide mechanical and electrical connection of the semiconductor die 110 to conductive features 142 of the circuit board 140. In other examples, different package forms and types can be used. The substrate trace and via routings provide desired electrical connections between the components of the device 100 and the solder ball leads 109.

The electronic device 100 has a semiconductor die 110 that is partially enclosed by the package structure 108. In the illustrated example, the semiconductor die 110 has conductive metal terminals 111 (e.g., copper pillars or bumps in FIG. 1) that are attached and directly electrically coupled by solder 112 to respective first conductive features along the top side of the substrate 107. Other electronic components (not shown) can be included, such as further semiconductor dies, passive or active surface mount components (e.g., resistors, capacitors, inductors, transformers, diodes, transistors, etc.) or combinations thereof, and which can be attached (e.g., soldered) to corresponding conductive features on the top side of the substrate 107. The package structure 108 extends on a portion of the top side of the substrate 107 and may extend underneath the bottom side 121 of the semiconductor die 110 in the flip-chip attached implementation as shown in FIG. 1. The electronic device 100 is shown in FIG. 1 installed on a system circuit board 140 having corresponding conductive features 142 on a top side thereof, with the conductive leads 109 of the substrate 107 electrically coupled to corresponding conductive features 142 of the circuit board 140 by solder of the solder ball terminals 109.

The semiconductor die 110 has opposite first and second sides 121 and 122 (e.g., respective bottom and top sides in the illustrated position of FIG. 1). The first side 121 is the die front side and the second side 122 is the die back side. The conductive terminals 111 are located along the first side 121 and are coupled to respective ones of the first conductive features of the substrate 107 by flip chip soldering via solder tips 112. The conductive metal terminals 111 in one example extend outward (e.g., downward) from the first side 121 of the semiconductor die 110 along the third direction Z (FIG. 1). The semiconductor die 110 also has respective lateral third and fourth sides 123 and 124 (FIGS. 1 and 1A) and lateral fifth and sixth sides 125 and 126 (FIG. 1A).

The first or bottom side 121 and the second or top side 122 are spaced apart from one another along the third direction Z. The respective lateral third and fourth sides 123 and 124 are spaced apart from one another along the first direction X, and the respective fifth and sixth sides 125 and 126 are spaced apart from one another along the second direction Y in the illustrated orientation. The sides 121 and 122 in one example extend in approximately parallel planes of the first and second directions (e.g., respective X-Y planes), although not a requirement of all possible implementations. The sidewalls 123 and 124 individually extend between the sides 121 and 122 and extend in approximately parallel planes of the second and third directions (e.g., respective Y-Z planes), although not a requirement of all possible implementations.

The semiconductor die 110 has an electrically and/or thermally conductive shield 130 with electrically and/or thermally conductive material that extends through the semiconductor die 110 from the first side 121 to the second side 122. In certain examples, the electrically and/or thermally conductive material of the electrically and/or thermally conductive shield 130 has a thermal conductivity that is greater than that of a semiconductor material of the semiconductor die 110. This facilitates good thermal performance of the electronic device 100 by providing a thermal path between the bottom and top (e.g., first and second) sides 121 of the semiconductor die 110. Moreover, conductive features of the substrate 107 include electrical connections to electrically couple the electrically and/or thermally conductive shield 130 to one or more respective terminals 109 of the substrate 107 as shown in FIG. 1. In this manner, the electrically and/or thermally conductive shield 130 is extended through the substrate 107 in certain examples to provide a thermal path to a host printed circuit board (e.g., 140 in FIG. 1).

The electrically and/or thermally conductive shield 130 in the illustrated example includes electrically and/or thermally conductive material filled vias 131 that extend through the semiconductor die 110 from the first side 121 to the second side 122, as well as an electrically and/or thermally conductive material layer 132 on at least a portion of the second side 122 of the semiconductor die 110, where the electrically and/or thermally conductive material layer 132 is electrically and mechanically connected to the electrically and/or thermally conductive material filled vias 131. In one implementation, the material layer 132 and the conductive material of the filled vias 131 is a contiguous thermally and electrically conductive structure, and the portions 131 and 132 can be formed in a single process. This provides a low impedance electrical path between the top side 102 of the electronic device 100 (e.g., the electrically and/or thermally conductive material layer 132) to the solder ball device terminals 109 and to conductive features of the host circuit board 140 to which the electronic device 100 is attached. The shield 130 can be advantageously connected to a ground plane or other suitable electrical reference node of the host circuit board 140. The conductive features 142 of the circuit board 140 in FIG. 1, for example, electrically couples the electrically and/or thermally conductive shield 130 to a ground plane of the circuit board 140, for example, to provide a grounded shield for the circuitry in the interior region of the semiconductor die 110. This helps to protect EMI sensitive circuitry in the interior region of the semiconductor die 110 from externally generated EMI or RFI signals, and/or to protect external devices from EMI or RFI generated by components are circuits within the interior region of the semiconductor die 110.

Moreover, the integrated shield structure provides a low thermal impedance heat conducting path between the material layer 132 and the conductive features of the circuit board 140. The shield 130 can thus operate as a top to bottom heat spreader, for example, to facilitate extraction of heat from hotspots or other high power circuit components within the interior region of the semiconductor die 110 and/or to protect thermally sensitive components are circuits from overheating by providing a cooling path to draw heat out of the semiconductor die 110. In the illustrated example, moreover, the package structure 108 partially encloses the semiconductor die 110 and exposes a portion of the electrically and/or thermally conductive shield 130 along a portion of the second side 122. This allows heat to be drawn out of the semiconductor die 110 in the upper direction in the illustrated orientation. In certain examples, an external heat sink (not shown) may be attached to the exposed top side of the semiconductor die, for example, attached by thermally conductive adhesive, not shown, to the top side of the material layer 132 of the shield 130.

As shown in FIG. 1A, the electrically and/or thermally conductive material filled vias 131 in one example laterally encircle (e.g., laterally surround) the interior portion of the semiconductor die 110. This provides a cage structure that operates as an electromagnetic shield as well as a thermal heat extraction path along the third direction Z in FIG. 1. In the illustrated example, the shield 130 which forms the cage structure includes multiple rows and columns of the electrically and/or thermally conductive material filled vias 131, although not a requirement of all possible implementations.

In addition, the illustrated example has a single electrically and/or thermally conductive shield 130 that surrounds the central portion of the semiconductor die 110 to facilitate thermal and/or electrical shielding benefits in operation of the electronic device 100. In other implementations, multiple protected regions can be provided with a corresponding electrically and/or thermally conductive shield 130 in a single semiconductor die 110 and/or multiple electrically and/or thermally conductive shields 130 can be created to surround respective portions of a semiconductor die and may be connected to a shared top material layer 132 and/or to a shared single substrate structure. In other implementations, the substrate 107 can include one or more corresponding shield extensions formed by the conductive features of the substrate 107, for example, to provide shared or separate electrical shield connections and/or shared or separate thermal extraction connections to a host circuit board 140. The grounded connection in certain implementations helps isolate parasitics in circuits from external sources like radio frequency interferences (RFI) to mitigate detrimental effects, and the described examples provide a solution to solve both thermal and EMI challenges concurrently.

Any suitable electrically and/or thermally conductive material can be used in forming the shield 130 and the portions 131, 132 thereof. In one example, the conductive material of the conductive shield 130 is or includes copper. In another example, the conductive material of the conductive shield 130 is or includes solder. In another example, the conductive material of the electrically conductive shield 130 is or includes boron nitride. In another example, the conductive material of the conductive shield 130 is or includes Ti/Ni/Ag. In another example, the conductive material of the conductive shield 130 is or includes graphene. In other implementations, the conductive material of the shield 130 can be combinations of the above or other suitable electrically and/or thermally conductive material.

As further shown in FIG. 1, the electronic device 100 in one example also includes an insulation layer 133 between the conductive material 131 of the conductive shield 130 and the semiconductor material of the semiconductor die 110. The insulation layer 133 can be or include silicon dioxide or other suitable electrical insulator material to help isolate the conductive material 131, 132 of the shield 130 from the silicon or other semiconductor material of the die 110. In one example, the electronic device 100 further includes an adhesion layer 134 between the insulation layer 133 and the conductive material of the conductive shield 130, for example, to help adhere the conductive material of the shield 130 to the insulation layer 133.

The described examples help achieve application-specific power requirements for FCCSP and other devices, particularly where standard over molded encapsulation is not sufficient from a thermal conductivity standpoint. This solution supplements the thermal performance obtained from an exposed die package by creating a lower thermal resistance path to a heat sink or to the circuit ambient, where the conductive material filled vias 131 and the top layer 132 of the shield 130 provide a higher thermally conductive material than silicon or other die semiconductor material. In addition, EMI shielding can be accomplished between top of the semiconductor die 110 and the substrate 107 with the vias 131 connecting copper pillars or bumps or other terminals 111 to a ground layer. The electronic device 100 can provide enhanced thermal and EMI performance without the added cost and manufacturing complexity of other approaches, such as engineering higher thermal conductivity epoxy molding compound (e.g., high K EMC), increasing semiconductor die thickness to improved lateral heat spreading, increased copper density in the substrate 107, use of a copper or other metal lid as a heat spreader for topside cooling, use of a grounded lid for EMI shielding, and/or metallizing a top layer of a substrate to facilitate grounding connections. The described examples also advantageously provide an integrated EMI shield with connections for a circuit board termination at a much lower manufacturing cost compared to sputter depositing copper or other metal along the top and sidewalls of a cingulate in semiconductor die.

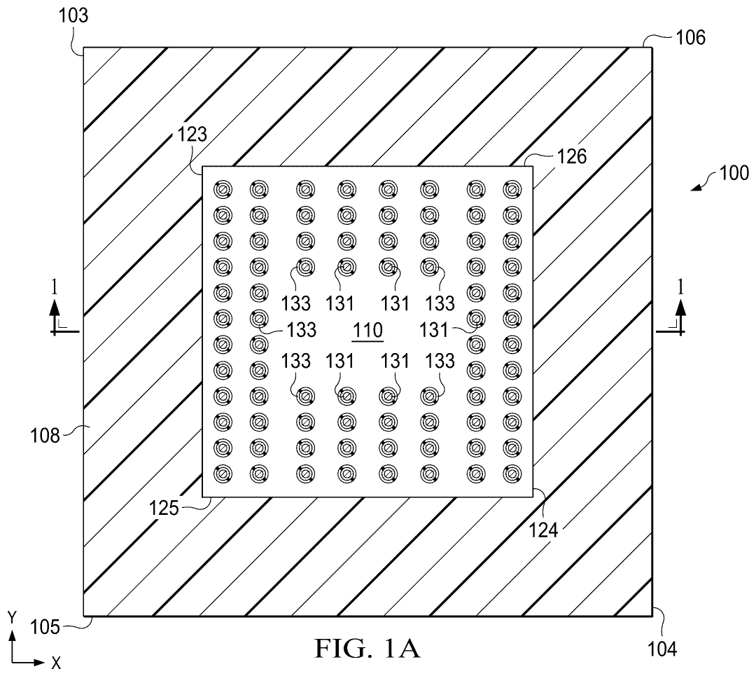

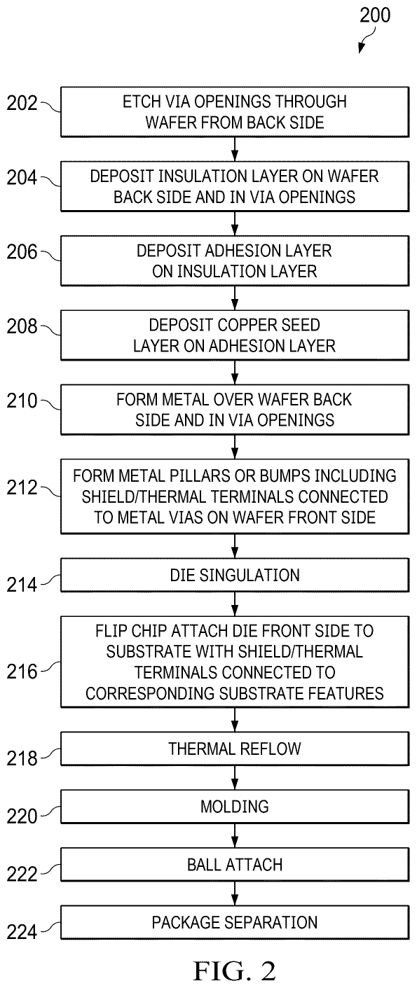

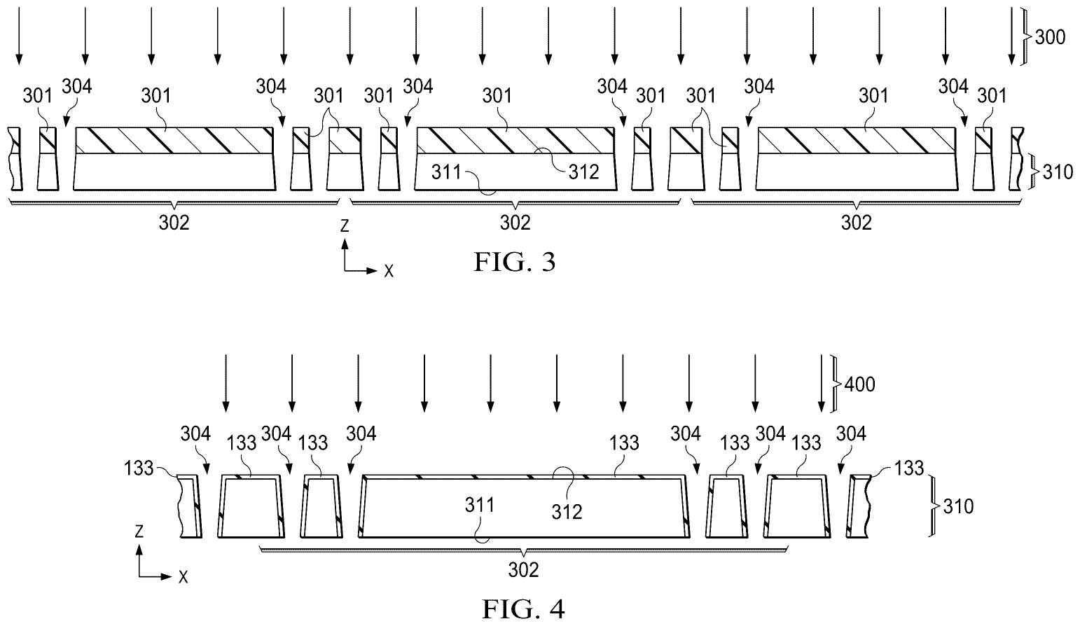

Referring also to FIGS. 2-14, FIG. 2 shows a method 200 of fabricating an electronic device, and FIGS. 3-14 illustrate the example electronic device 100 undergoing fabrication processing according to an example implementation of the method 200. The method 200 begins at 202 in FIG. 2 with forming via openings extending through a processed wafer. FIG. 3 shows one example, in which an etch process 300 is performed using a an etch mask 301. The etch process 300 forms via openings 304 in each unit area 302 (e.g., prospective die area) of a starting wafer 310. The etched via openings 304 extend from a first (e.g., bottom) side 311 of a wafer 310 to an opposite second (e.g., top) side 312 of the wafer 310 as shown in FIG. 3, and the openings 304 may include somewhat tapered sidewalls depending on the particular etch process 300 used. In one example, the etch mask 301 is patterned such that the etched via openings 304 laterally encircle an interior portion of a prospective die area 302 of the wafer 310 (e.g., FIG. 1A above).

The method 200 continues with filling the via openings 304 with conductive material. FIG. 2 shows one example, in which an insulation layer 133 and an adhesion layer 134 are formed at 204 and 206 along the sidewalls of the via openings 304 and along the top side 312 of the wafer 310 prior to filling the via openings 304 with the conductive material at 208 and 210. In other implementations, the processing at 204 and/or 206 can be omitted. In the illustrated example, an insulation layer is deposited at 204. FIG. 4 shows one example, in which a process 400 is performed that deposits or otherwise forms the insulation layer 133 along sidewalls of the via openings 304 and along the second side 312 of the wafer 310.

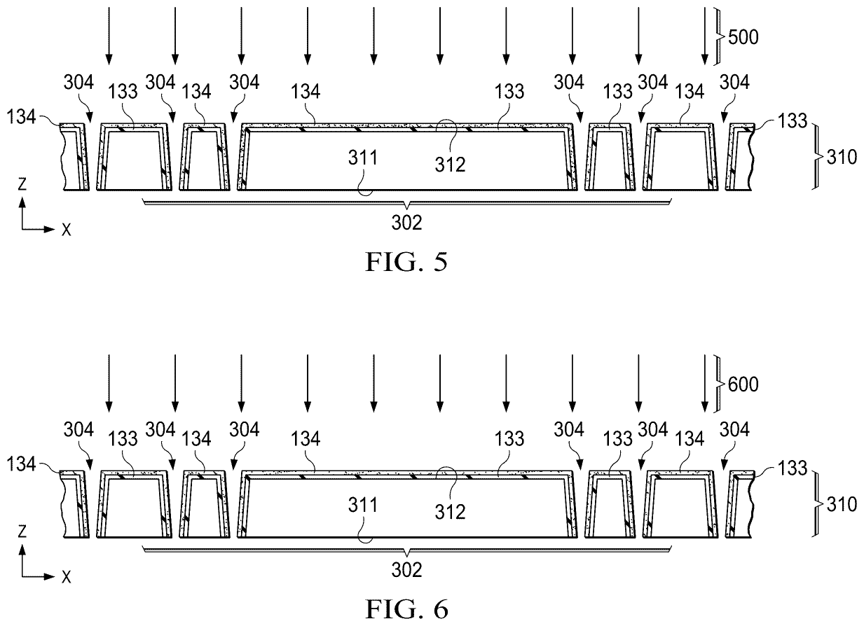

At 206 in FIG. 2, the illustrated example continues with forming an adhesion layer on the insulation layer. FIG. 5 shows one example, in which a deposition process 500 is performed that deposits an adhesion layer 134 on the insulation layer 133 along the wafer second side 312 and the sidewalls of the via openings 304. Any suitable adhesion layer material and thickness can be used that helps subsequent adhesion of conductive material to the insulation layer 133.

Any suitable processing steps and materials can be used to fill the via openings 304 and cover the wafer topside 312 with conductive material. In one example, copper or other metal material is electroplated. In this example, a seed layer is deposited at 208 followed by electroplating at 210 in FIG. 2. FIG. 6 shows one example, in which a sputter deposition process 600 is performed that deposits a thin copper seed layer (not shown in FIG. 6) on the adhesion layer 134 along the sidewalls of the via openings 304 and over the wafer topside 312.

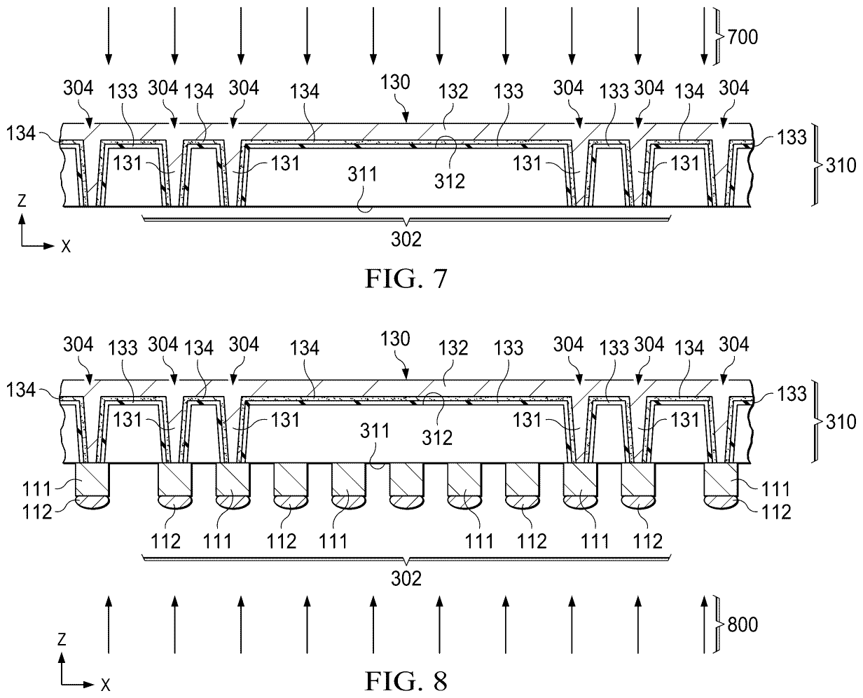

This example continues at 210 in FIG. 2 with electroplating to form conductive material over the wafer backside 312 and in the via openings 304. FIG. 7 shows one example, in which an electroplating process 700 is performed that deposits copper or other suitable electrically and/or thermally conductive material (e.g., metal) 131, 132 that extends in the via openings 304 through the semiconductor die 110 from the first side 311 to the second side 312 (e.g., the opening fill material 134) and covers a portion of the second side 312 of the wafer 310 (e.g., material layer 132 in the figures). In one example, the electroplating process 700 continues until a final desired backside metal thickness is achieved. In other examples, different electrically and/or thermally conductive material can be deposited or otherwise formed to fill the via openings 304 and two extend along at least a portion of the second side 312 of the wafer. In other example implementations, the conductive shield 130 includes solder or boron nitride formed by performing a screening process (not shown) that forms the solder or boron nitride in the via openings 304 through the semiconductor die 110 and on the portion of the second side 312 of the wafer 310. In another non-limiting example, the conductive shield 130 includes graphene that can be formed in the via openings 304 and along the second side 312 of the wafer 310 by any suitable processing techniques.

The method 200 continues at 212 in FIG. 2 with terminal formation to form bumps or copper pillars along the first (e.g., front) side 311 of the wafer 310. FIG. 8 shows one example, in which a bumping process 800 is performed that forms conductive metal (e.g., copper) terminals 111 along the first side 311 of the wafer 310. The terminals 111 includes connections for electrical components formed in the interior protected region of each unit area 302 of the semiconductor wafer 310, as well as shield connection terminals 111 that are electrically and mechanically connected to the via opening fill metal 131. In one example solder tips 112 are formed on the distal ends of the conductive terminals 111 of the semiconductor wafer 310 in each unit area 302, such as by dipping or other suitable technique. In another example, the solder 112 can be applied (e.g., by dipping) to the distal ends of the terminals 111 after die singulation before flip chip attachment to a substrate, or solder can be applied as a paste to target locations along the conductive features of the substrate before attachment of a simulated die with the terminals 111 attached to respective solder paste locations.

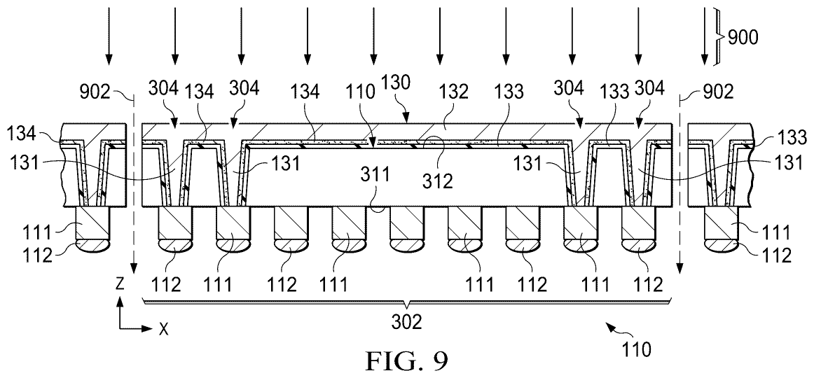

The method 200 continues at 214 in FIG. 2 in the illustrated example with die singulation. FIG. 9 shows one example, in which a die singulation or separation process 900 is performed that separates the individual semiconductor dies 110 from one another and from the starting wafer structure. Any suitable die singulation process 900 and tooling can be used, for example, etching, grinding, laser ablation, saw cutting, etc., or combinations thereof. The die singulation process 900 separates adjacent semiconductor dies 110 from one another along lines 902 (e.g., scribe streets) and creates the lateral sides 123-126 of the individual semiconductor dies 110 with the conductive shield 130 extending in the via openings 304 from the first die side 111 to the second die side 112 and covering a portion of the second die side 112, and with the conductive terminals 111, 112 positioned along the first die side 111 as illustrated and described above in connection with FIGS. 1 and 1A.

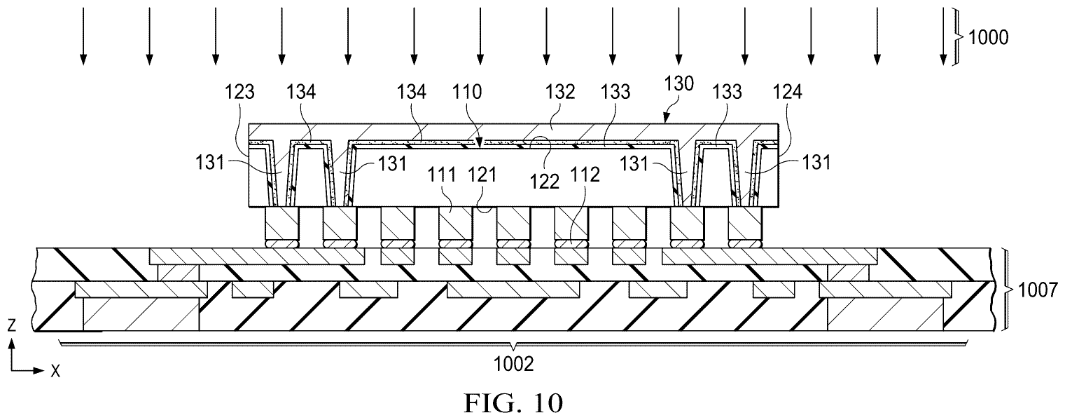

The method 200 continues at 216 in FIG. 2 with attaching the conductive terminals 111, 112 along the first side 121 of the semiconductor die 110 to respective conductive features of a substrate 107. FIG. 10 shows one example, in which a die attach process 1000 is performed using a starting substrate panel array 1007 with multiple unit areas 1002, one of which is illustrated. In one implementation, solder paste is formed (e.g., by printing, silk screening, dispensing, or other suitable technique) in select portions on certain conductive features of a top side of the substrate 1007. In another example, the illustrated solder tips 112 are formed on the distal ends of the conductive terminals 111 of the semiconductor die 110, such as by dipping, or solder 112 can be provided at the ends of the conductive terminals 111 during wafer processing (e.g., at 212 in FIG. 2 above). In one example, the semiconductor dies 110 are positioned with the conductive terminals 111 on respective conductive features in each unit area 1002 of the substrate panel array 1007, for example, using automated pick and place equipment (not shown). The illustrated example is a flip-chip die attach process 1000, which can be used alone or in combination with other component attachment techniques and equipment. The method in certain implementations can include any desired redesign or initial design of the unit areas 1002 of the substrate panel array 1007 such that the conductive features of the substrate 1007 include electrical connections to electrically couple the conductive shield 130 to subsequently formed terminals 109 of the substrate 107.

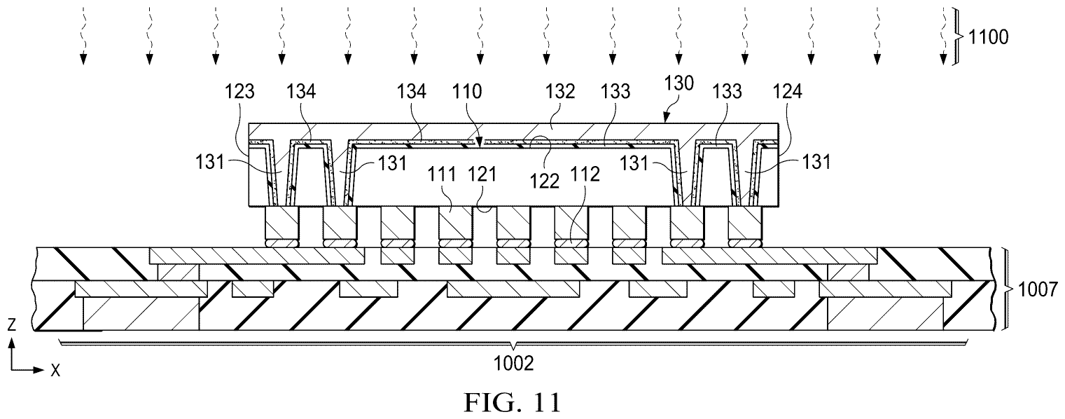

The method 200 continues at 218 in FIG. 2 with solder reflow processing. FIG. 11 shows one example, in which a thermal process 1100 is performed that reflows the solder paste to form solder connections between the semiconductor die copper pillar terminals 111 and the corresponding conductive metal features on the top side of the substrate panel array 1007. The flip-chip die attach processing at 216 and 218 in FIG. 2 can also include similar processing for attaching surface mount components (e.g., passive resistors, capacitors, inductors, transformers, active components such as transistors, etc., not shown) with terminals positioned on solder paste previously applied at 216 to corresponding conductive metal features of the substrate panel array 1007, followed by thermal reflow at 218 to form corresponding solder connections of the attached components to the multilevel package substrate panel array 1007.

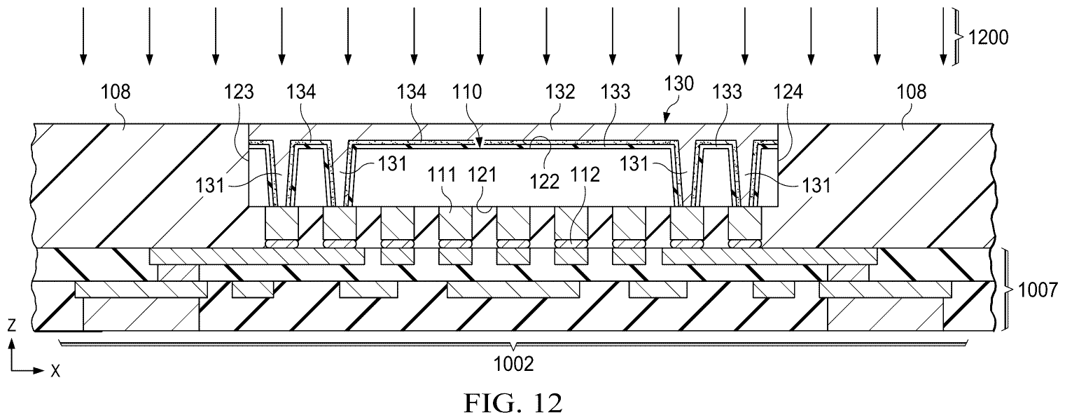

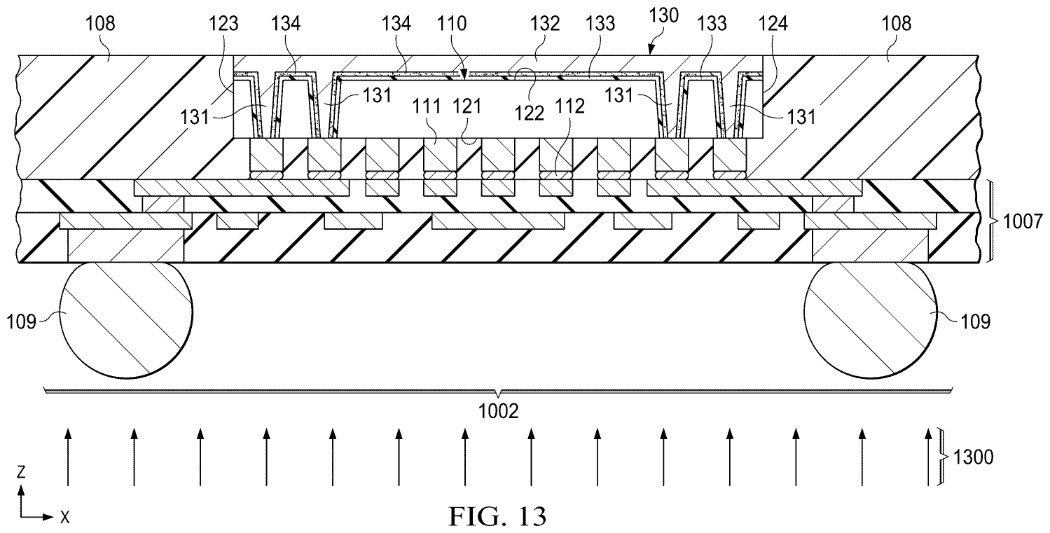

The method 200 in one example continues at 220 in FIG. 2 with formation of the package structure 108 that partially encloses the semiconductor die 110 and exposes a portion of the conductive shield 130 along a portion of the second die side 122. In other examples, the package structure 108 and the processing at 220 can be omitted. FIG. 12 shows one example, in which a molding process 1200 is performed using a mold (not shown) that has a cavity with a top surface is generally planar and extends across the illustrated unit area 1002 and adjacent unit areas 1002. The mold in one example contacts the top side of the plated conductive material layer 132 in each unit area 1002 of the substrate panel array 1007 such that no molding compound flows or otherwise covers the top side of the material layer 132 in the finished electronic devices.

In one implementation, a single mold cavity can be used to create a molded package structure 108 in each unit area 1002, which are subsequently separated during package separation processing (e.g., at 224 in FIG. 2). In other implementations, the individual mold cavities can be used for each unit area 1002 or groups of fewer than all unit areas 1002 can be included within a shared mold cavity (not shown). The molding process 1200 forms the molded package structure 108, which extends on the top side of the substrate 1007, on the lateral sidewalls 123 and 124 and on the bottom 121 of the semiconductor die 110, and the molded package structure 108 extends into and fills the indents 120. In one example, the molding process 1200 forms mold compound 108 between the bottom side 121 of the individual semiconductor dies 110 and the top side of the substrate 1007 that extends between the conductive terminals 111 as shown in FIG. 12.

In the illustrated example, the method 200 includes terminal formation by ball grid array ball attach processing at 222 in FIG. 2. FIG. 13 shows one example, in which a solder ball attachment process 1300 is performed (e.g., ball drop) to form and attach the solder balls 109 to conductive features along the bottom side of the substrate panel array 1701. In the illustrated example, the solder balls 109 are attached to corresponding conductive features on the outer periphery of the bottom side of each unit area 1002 of the substrate panel array 1701, although not a requirement of all possible implementations.

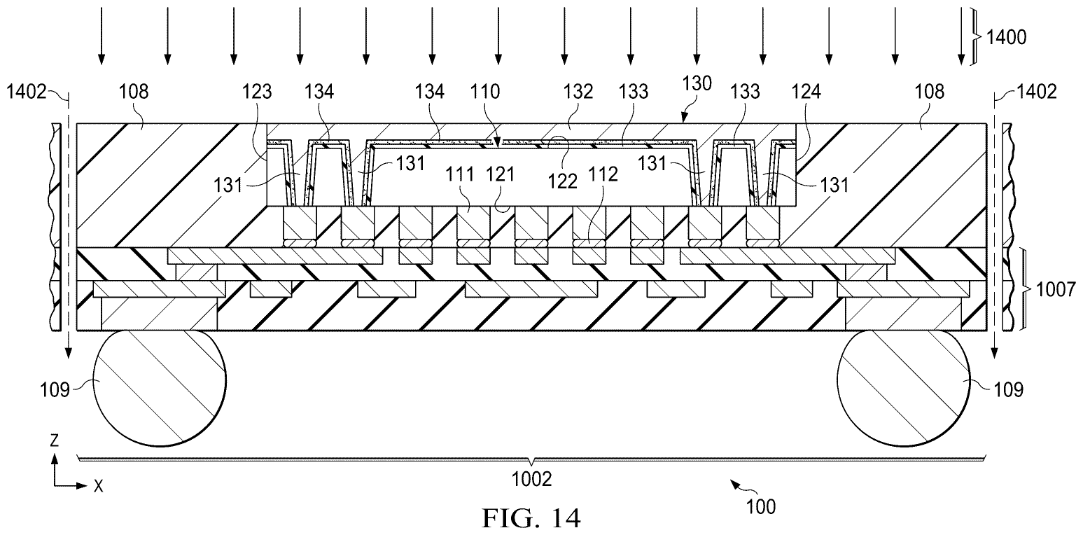

In one implementation, the method 200 proceeds with package separation at 224 in FIG. 2. FIG. 14 shows one example, in which a package separation process 1400 is performed that separates individual packaged electronic devices 100 from the starting substrate panel array structure 1701 along lines 1402 in scribe streets between adjacent rows and columns of unit areas of the starting substrate panel array structure. In one implementation, the separation process 1400 includes saw cutting. In other implementations, one or more different separation processes can be used, for example, saw cutting, laser cutting, chemical etching, or combinations thereof, etc. The described method 200 provides significant cost savings in constructing a thermal shield and/or an EMI shield integral to the finished packaged electronic devices 100, particularly compared to depositing conductive metal along the top and lateral sides of a semiconductor die prior to flip chip attachment on a substrate.

The above examples are merely illustrative of several possible implementations of various aspects of the present disclosure, wherein equivalent alterations and/or modifications will occur to others skilled in the art upon reading and understanding this specification and the annexed drawings. Modifications are possible in the described examples, and other implementations are possible, within the scope of the claims.

What is claimed is:

1. An electronic device, comprising:
a substrate having conductive features; and
a semiconductor die having opposite first and second sides, conductive terminals along the first side, and a conductive shield with conductive material that extends through the semiconductor die from the first side to the second side, the conductive terminals coupled to respective ones of the conductive features of the substrate.

2. The electronic device of claim 1, wherein the conductive shield includes conductive material filled vias that extend through the semiconductor die from the first side to the second side, and a conductive material layer on at least a portion of the second side, the conductive material layer connected to the conductive material filled vias.

3. The electronic device of claim 2, wherein the conductive material filled vias laterally encircle an interior portion of the semiconductor die.

4. The electronic device of claim 1, wherein the conductive material of the conductive shield has a thermal conductivity greater than that of a semiconductor material of the semiconductor die.

5. The electronic device of claim 1, further comprising a package structure that partially encloses the semiconductor die and exposes a portion of the conductive shield along a portion of the second side.

6. The electronic device of claim 1, wherein the conductive material of the conductive shield includes copper.

7. The electronic device of claim 1, wherein the conductive material of the conductive shield includes solder.

8. The electronic device of claim 1, wherein the conductive material of the conductive shield includes boron nitride.

9. The electronic device of claim 1, wherein the conductive material of the conductive shield includes graphene.

10. The electronic device of claim 1, further comprising an insulation layer between the conductive material of the conductive shield and a semiconductor material of the semiconductor die.

11. The electronic device of claim 1, further comprising an adhesion layer between the insulation layer and the conductive material of the conductive shield.

12. The electronic device of claim 1, wherein the conductive features of the substrate include electrical connections to electrically couple the conductive shield to terminals of the substrate.

13. A system, comprising:
a circuit board having a conductive feature; and
an electronic device, including:
a substrate having conductive features, and a conductive terminal that is soldered to the conductive feature of the circuit board; and
a semiconductor die having opposite first and second sides, conductive terminals along the first side, and a conductive shield with conductive material that extends through the semiconductor die from the first side to the second side, the conductive terminals coupled to respective ones of the conductive features of the substrate.

14. The system of claim 13, wherein the conductive features of the substrate include electrical connections to electrically couple the conductive shield to the conductive terminal of the substrate.

15. The system of claim 14, wherein the conductive feature of the circuit board electrically couples the conductive shield to a ground plane of the circuit board.

16. A method of fabricating an electronic device, the method comprising:
forming via openings extending from a first side of a wafer to an opposite second side of the wafer;
forming a conductive shield that extends in the via openings through the semiconductor die from the first side to the second side and covers a portion of the second side of the wafer; and
forming conductive terminals along the first side of the wafer.

17. The method of claim 16, further comprising:
separating a semiconductor die with from the wafer, the semiconductor die having opposite first and second die sides, the conductive shield extending in the via openings from the first die side to the second die side and covering a portion of the second die side, and the conductive terminals along the first die side; and
attaching the conductive terminals along the first die side of the semiconductor die to respective conductive features of a substrate.

18. The method of claim 17, further comprising forming the conductive features of the substrate including electrical connections to electrically couple the conductive shield to terminals of the substrate.

19. The method of claim 17, further comprising forming a package structure that partially encloses the semiconductor die and exposes a portion of the conductive shield along a portion of the second die side.

20. The method of claim 16, wherein the via openings laterally encircle an interior portion of a prospective die area of the wafer.

21. The method of claim 16, wherein the conductive shield includes conductive material with a thermal conductivity greater than that of a semiconductor material of the wafer.

22. The method of claim 16, further comprising depositing an insulation layer along sidewalls of the via openings and along the second side of the wafer before forming the conductive shield.

23. The method of claim 22, further comprising depositing an adhesion layer on the insulation layer before forming the conductive shield.

24. The method of claim 16, wherein the conductive shield includes copper.

25. The method of claim 24, wherein forming the conductive shield includes performing an electroplating process to deposit the conductive shield.

26. The method of claim 16, wherein the conductive shield includes solder or boron nitride.

27. The method of claim 26, wherein forming the conductive shield includes performing a screening process that forms the solder or boron nitride in the via openings through the semiconductor die and on the portion of the second side of the wafer.

28. The method of claim 16, wherein the conductive shield includes graphene.
